(19) United States
(12) Patent Application Publication
(10) Pub. No.: US 2002/0197835 A1
(43) Pub. Date: Dec. 26, 2002

(54) Anti-reflective coating and methods of making the same

(76) Inventors: Sey-Ping Sun, Austin, TX (US); David E. Brown, Austin, TX (US); Kin-Sang Lam, Austin, TX (US)

Correspondence Address: TIMOTHY M HONEYCUTT ATTORNEY AT LAW, P O BOX 1577, CYPRESS, TX, 77410, US

(21) Appl. No.: 09/875,681

(22) Filed: Jun. 6, 2001

(51) Int. Cl. H01L 21/3205; H01L 21/4763; H01L 21/31; H01L 21/469

(52) U.S. Cl. 438/585; 438/952

(57) ABSTRACT

A circuit device incorporating an anti-reflective coating and methods of fabricating the same are provided. In one aspect, a method of processing a substrate is provided that includes forming a film on the substrate and forming an anti-reflective coating on the film by first forming a silicon-rich nitride film on the film in a first plasma atmosphere and thereafter exposing the silicon-rich nitride film in-situ to a second plasma atmosphere containing oxygen to convert an upper portion of the silicon-rich nitride film to silicon oxynitride. Variability in the optical properties of the anti-reflective coating substantially reduced, resulting in improved UV lithographic patterning of etch masking.

### BACKGROUND OF THE INVENTION

1. Field of the Invention

This invention relates generally to semiconductor processing, and more particularly to a circuit device incorporating an anti-reflective coating and to methods of making the same.

2. Description of the Related Art

The fabrication of amorphous and polysilicon conductor structures involves a litany of fabrication steps. Most conventional processes involve the sequential deposition, resist masking and etching of selected portions of an amorphous or polysilicon film. Blanket chemical vapor deposition (“CVD”) is frequently used to apply the polysilicon film, which is rendered conductive by in-situ doping or via subsequent impurity implants. Masking is accomplished by deposition of a resist film, baking, exposure to actinic radiation and development in a developer solvent. Pattern etching follows resist development.

During resist exposure, actinic radiation is projected onto the resist film to alter the chemical characteristics of selected portions thereof. The quality of the subsequently developed image depends on, among other things, the optical properties of the resist and the films underlying the resist. In amorphous and polysilicon patterning, oxide films frequently underlie the deposited poly or amorphous film. Highly reflective films, such as polysilicon and metals, tend to reflect significant quantities of radiation back upward and into the resist. This reflected radiation can produce interference patterns within the resist that impact the quality of the image.

During exposure development of the etch mask resist, standing waves produced during exposure may result in so-called “footing” in the edges of the patterned resist openings. In order to suppress the effects of standing waves, an anti-reflective coating of silicon nitride is commonly formed underneath the resist mask. In one conventional fabrication process, the optical properties of the silicon nitride film are modified by depositing the silicon nitride film in a two-step process. In the first stage, low pressure CVD (“LPCVD”) is used to establish the majority of the thickness of the nitride film. Thereafter, a silicon-rich nitride film is established on the LPCVD nitride film, again by LPCVD, albeit with altered flow rates for silicon source and nitrogen source gases. The use of LPCVD is a relatively high temperature process and thus consumes thermal budget. The LPCVD silicon nitride film, while having better optical properties than a comparable non-silicon-rich film, nevertheless tends to form with higher stresses than a plasma enhanced CVD (“PECVD”) nitride film. Furthermore, manufacturing experience has demonstrated that LPCVD silicon-rich nitride furnace processes tend to produce silicon-rich nitride films with variations in film thickness, refractive index and extinction coefficient. These variations produce undesirable variations in resist exposure and development.

The present invention is directed to overcoming or reducing the effects of one or more of the foregoing disadvantages.

### SUMMARY OF THE INVENTION

In accordance with one aspect of the present invention, a method of processing a substrate is provided that includes forming a film on the substrate and forming an anti-reflective coating on the film by first forming a silicon-rich nitride film on the film in a first plasma atmosphere and thereafter exposing the silicon-rich nitride film in-situ to a second plasma atmosphere containing oxygen to convert an upper portion of the silicon-rich nitride film to silicon oxynitride.

In accordance with another aspect of the present invention, a method of processing a substrate is provided that includes forming a polysilicon film on the substrate and forming an anti-reflective coating on the polysilicon film by first forming a silicon-rich nitride film on the polysilicon film by plasma enhanced chemical vapor deposition and thereafter exposing the silicon-rich nitride film in-situ to a plasma atmosphere containing oxygen to convert an upper portion of the silicon-rich nitride film to silicon oxynitride. A mask is formed on the silicon-rich nitride film, and unmasked portions of the silicon-rich nitride film are etched to define a circuit structure from the polysilicon film.

In accordance with another aspect of the present invention, a circuit device is provided that includes a semiconductor substrate and a film positioned on the substrate. An anti-reflective coating is positioned on the film. The anti-reflective coating has a silicon-rich nitride portion positioned on the film and an oxynitride interface positioned on the silicon-rich nitride portion.

### BRIEF DESCRIPTION OF THE DRAWINGS

The foregoing and other advantages of the invention will become apparent upon reading the following detailed description and upon reference to the drawings in which:

FIG. 1 is a cross-sectional view of a substrate depicting initial circuit device processing with the aid of an anti-reflective coating in accordance with one exemplary embodiment of the present invention;

FIG. 2 is a cross-sectional view like FIG. 1 depicting further processing of the substrate in accordance with the present invention;

FIG. 3 is a cross-sectional view like FIG. 2 depicting further processing of the substrate in accordance with the present invention;

FIG. 4 is a cross-sectional view like FIG. 3 depicting further processing of the substrate in accordance with the present invention;

FIG. 5 is a cross-sectional view like FIG. 4 depicting formation of the anti-reflective coating on the substrate in accordance with the present invention;

FIG. 6 is a cross-sectional view like FIG. 5 depicting formation of an oxynitride interface on the anti-reflective coating in accordance with the present invention;

FIG. 7 is a cross-sectional view like FIG. 6 depicting the masking of the anti-reflective coating in accordance with the present invention;

FIG. 8 is a cross-sectional view like FIG. 7 depicting the definition of circuit devices in accordance with the present invention;

FIG. 9 is a cross-sectional view like FIG. 8 depicting further processing of the circuit devices in accordance with the present invention;

FIG. 10 is a cross-sectional view like FIG. 9 depicting further processing of the circuit devices in accordance with the present invention;

FIG. 11 is a cross-sectional view of a substrate depicting initial circuit device processing with the aid of an anti-reflective coating in accordance with an alternate exemplary embodiment of the present invention;

FIG. 12 is a cross-sectional view like FIG. 11 depicting formation of the anti-reflective coating on the substrate in accordance with the present invention;

FIG. 13 is a cross-sectional view like FIG. 12 depicting formation of an oxynitride interface on the anti-reflective coating in accordance with the present invention;

FIG. 14 is a cross-sectional view like FIG. 13 depicting the masking of the anti-reflective coating in accordance with the present invention;

FIG. 15 is a cross-sectional view like FIG. 14 depicting the definition of circuit devices in accordance with the present invention; and

FIG. 16 is a cross-sectional view like FIG. 15 depicting further processing of the circuit devices in accordance with the present invention.

### DETAILED DESCRIPTION OF SPECIFIC EMBODIMENTS

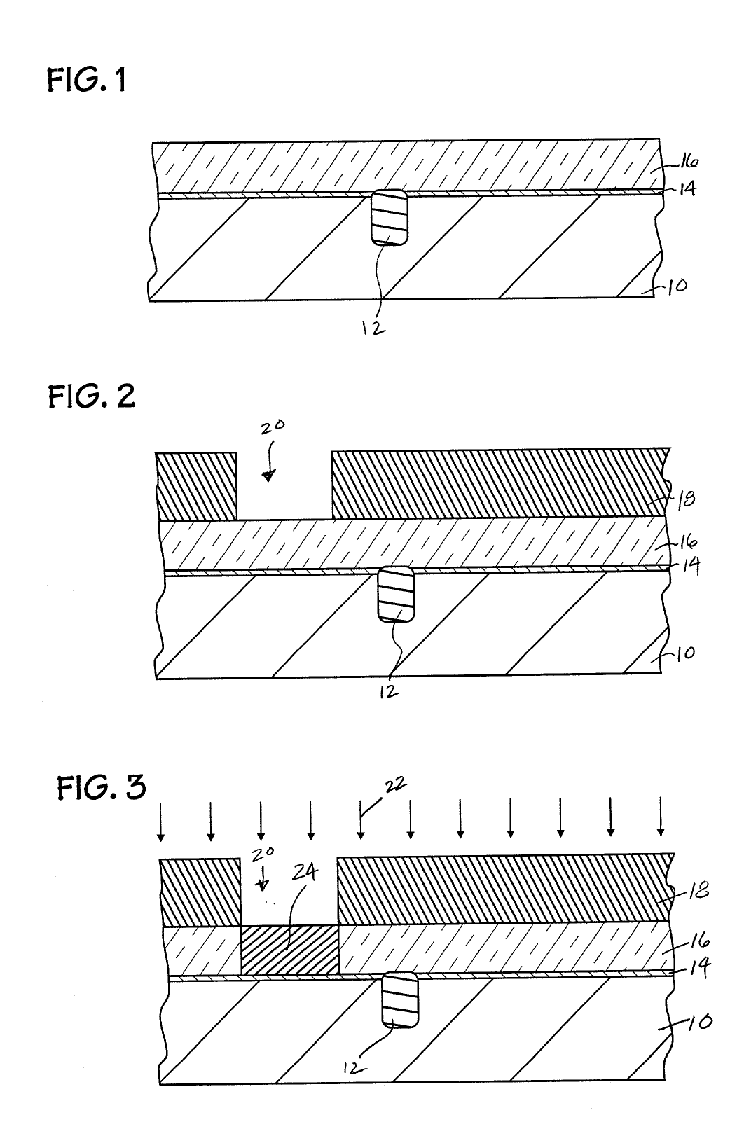

In the drawings described below, reference numerals are generally repeated where identical elements appear in more than one figure. FIGS. 1-10 illustrate cross-sectional views of an exemplary embodiment of a semiconductor substrate 10 undergoing processing leading to the formation of circuit devices. As described below, the process entails improved fabrication of an anti-reflective coating for enhanced resist exposure. The substrate 10 may be composed of p-doped silicon, n-doped silicon, silicon-on-insulator or other suitable substrate materials. Referring initially to FIG. 1, an isolation structure 12 is formed in the substrate 10. The isolation structure 12 may be a trench isolation structure or a LOCOS structure as desired and may be composed of oxide, doped glass, nitride, laminates of these or the like. A dielectric film 14 is formed on the substrate 10 and may be composed of oxide, dielectric film 14 of oxide, nitride, laminates of these or the like. In an exemplary embodiment, the dielectric film 14 is composed of oxide with a thickness of about 50 to 150 Å, and may be applied by thermal oxidation or CVD.

Still referring to FIG. 1, a film 16 is formed on the substrate 10. In the illustrated embodiment, the film 16 is composed of polycrystalline silicon. However, as the benefits of the present invention may be realized in circumstances where an anti-reflective coating is needed for resist exposure, the film 16 may be composed of a variety of conducting, non-conducting or semiconducting materials as desired. In this exemplary embodiment, the polysilicon film 16 has a thickness of about 1400 to 1800 Å. Through subsequent processing, the film 16 will be patterned into circuit structures suitable for gate electrodes, conductor lines, local interconnects or the like. Well-known CVD techniques may be used to deposit the polysilicon film 16.

Conductivity rendering impurities may be introduced into the polysilicon 16 at various stages in the process flow. Lighter weight species, such as boron, may be supplied via later-performed source/drain implants with relatively uniform distributions. However, reliance on source/drain implants to dope the polysilicon 16 may be problematic where the source/drain implant energies are tailored for shallow junctions. In this circumstance, a step dedicated to n+ doping of the polysilicon 16 may be appropriate. To this end, and as shown in FIG. 2, a mask 18 is patterned on the polysilicon film 16 with an opening 20 corresponding to the desired layout of one of the portions slated to receive impurities. Well-known photoresist materials, application and development techniques may be used to apply and pattern the mask 20.

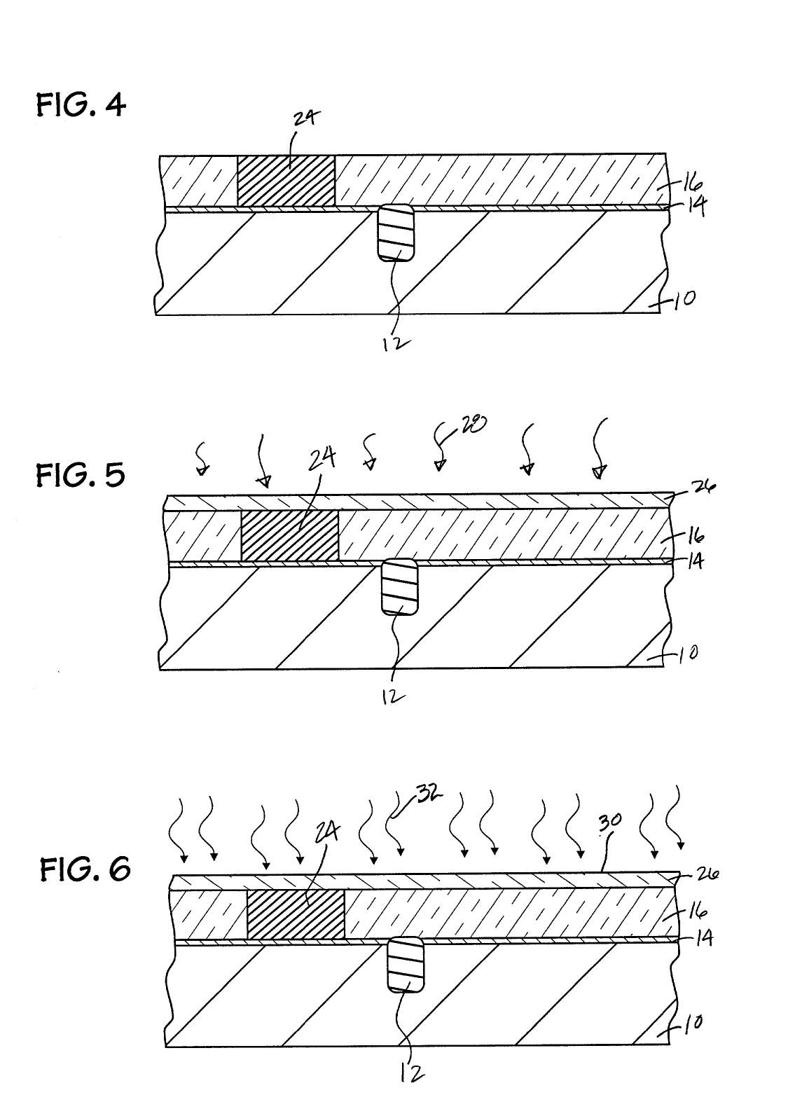

Referring now to FIGS. 3 and 4, impurity ions 22 are introduced into the polysilicon film 16 to render a portion 24 thereof conductive. The ions 22 may be introduced by ion implantation or diffusion as desired. In an exemplary embodiment, phosphorus ions 22 are implanted at a dosage of about 1E15 to 8E15 ions/cm⁻² and an energy of about 20 to 40 keV. The implant may be at 0° tilt and 40° twist. Following implant, the mask 18 is stripped by ashing, solvent stripping, combinations of these techniques or the like as shown in FIG. 4.

Masking and etching processes are next performed to pattern the polysilicon film 16 into conductor structures. The masking of the film 16 is facilitated by forming an anti-reflective coating on the film 16 prior to resist deposition. Referring now to FIG. 5, the anti-reflective coating 26 is formed on the polysilicon film 16 in a two-stage process. In the first stage, a PECVD silicon nitride deposition process is performed to establish a silicon nitride film with a silicon-rich composition. The thickness of the film may be about 160 to 240 Å. A plasma atmosphere 28 of a silicon source gas, such as silane or dichlorosilane, is mixed with a nitrogen source gas, such as ammonia, to establish the nitride film 16. The process conditions may be as follows:

TABLE 1

| | |
|---|---|
| Temperature | about 370 to 430° C. |
| Pressure | about 1.0 to 2.0 torr |
| High Frequency rf Power | about 250 to 450 watts |
| (@ 13.56 MHz) | |
| Low Frequency Power | about 160 to 360 watts |
| Silane Flow Rate | about 600 to 740 sccm |
| Ammonia Flow Rate | about 1100 to 1500 sccm |
| Nitrogen Flow Rate | about 2500 to 3500 sccm |
| Temperature Soak Time | about 10 to 30 seconds |
| Station Deposition Time | about 1.0 to 2.0 seconds |

Experiments using the foregoing parameters have demonstrated surprisingly good results and suggest that a silane-to-ammonia ratio of about 0.51 to 0.61 is important to obtaining a desirable silicon-rich character for the nitride film 26 for deep UV photolithography.

The PECVD process for depositing the silicon-rich nitride anti-reflective coating 26 is carried out at a relatively low temperature and thus results in lower stresses in the deposited film 26. Furthermore, the silicon-rich character of the film 26 provides enhanced anti-reflective coating properties for subsequent lithographic patterning using deep UV exposure and resists.

The anti-reflective coating properties of the silicon-rich nitride film 26 are further enhanced by the establishment thereon of the oxynitride interface 30 by treatment in a plasma atmosphere 32 as shown in FIG. 6. The interface 30 may have a thickness of about 20 to 40 Å. In an exemplary embodiment, the process conditions may be as follows:

TABLE 2

| | |
|---|---|
| Temperature | about 380 to 420° C. |
| Pressure | about 2.2 to 2.6 torr |
| High Frequency rf Power | about 700 to 800 watts |
| (@ 13.56 MHz) | |
| Nitrous Oxide Flow Rate | about 600 to 800 sccm |
| Treatment Time | about 20 to 60 seconds |
| Temperature Soak | about 10 to 30 seconds |
| Station Deposition Time | about 2.0 to 8.0 seconds |

One goal of the plasma treatment is to provide the anti-reflective coating 26 with optical properties that favor resist exposure with diminished footing. In an exemplary embodiment suitable for resist exposure at deep UV (248 nm), the anti-reflective coating 26 may be formed with an extinction coefficient k of about 0.65 to 0.75, an index of refraction n of about 2.45 to 2.55 and a reflectance of about 4 to 10%. These ranges are believed to provide desired anti-reflective coating, that is, optical properties so that standing wave effects during resist exposure are diminished.

The establishment of the oxynitride interface 30 satisfies an auxiliary goal of providing an interface that limits chemical reactions between amine groups in the later-formed resist mask and the underlying anti-reflective coating 26. If such chemical interactions go unchecked, the integrity and optical properties of the resist mask may be adversely affected.

An oxygen bearing species, nitrous oxide, is used for the plasma treatment. Optionally, other oxygen bearing species, such as, for example oxygen, nitric oxide or nitrogen dioxide may be used as well.

Note that the various processes to form the anti-reflective coating 26 involve plasma conditions and relatively low temperatures. This commonality of conditions suggests the possibility of fabricating the anti-reflective coating 26 using in-situ processing. In this way, the anti-reflective coating 26 and the overlying oxynitride interface 30 may be fabricated using plasma in lieu of lengthy furnace heating and without breaking vacuum. Better control over film contamination and native oxide formation is thus achievable with superior throughput.

Experiments have demonstrated that the process of the present invention yields an anti-reflective coating with substantially reduced variability in optical properties. The following tables summarize the results for wafers sampled from various lots. Tables 3 and 4 show the results for five sample wafers processed using the PECVD process of the present invention before and after plasma treatment. Tables 5 and 6 show the results for five sample wafers processed using conventional LPCVD processing.

TABLE 3
PECVD Anti-Reflective Coating Before Plasma Treatment

| | Anti-Reflective | | | |
|---|---|---|---|---|
| | Coating | Refractive | Extinction | |
| Wafer | Thickness (Å) | Index n | Coefficient k | Reflectance |
| 1 | 195.3 | 2.48 | 0.726 | 0.0669 |
| 2 | 192.9 | 2.49 | 0.730 | 0.0652 |
| 3 | 192.2 | 2.49 | 0.732 | 0.0646 |
| 4 | 192.7 | 2.48 | 0.730 | 0.0646 |
| 5 | 190.9 | 2.48 | 0.730 | 0.0623 |

TABLE 4
PECVD Anti-Reflective Coating After Plasma Treatment

| | Anti-Reflective | | | |
|---|---|---|---|---|
| | Coating | Refractive | Extinction | |
| Wafer | Thickness (Å) | Index n | Coefficient k | Reflectance |
| 1 | 194.0 | 2.45 | 0.715 | 0.0577 |
| 2 | 191.6 | 2.45 | 0.718 | 0.0562 |
| 3 | 190.9 | 2.45 | 0.720 | 0.0559 |
| 4 | 191.4 | 2.45 | 0.718 | 0.0557 |
| 5 | 189.8 | 2.44 | 0.718 | 0.0540 |

TABLE 5
LPCVD Anti-Reflective Coating Before Plasma Treatment

| | Anti-Reflective | | | |
|---|---|---|---|---|
| | Coating | Refractive | Extinction | |
| Wafer | Thickness (Å) | Index n | Coefficient k | Reflectance |
| 1 | 200.0 | 2.41 | 0.913 | 0.1066 |
| 2 | 199.1 | 2.48 | 0.771 | 0.0826 |
| 3 | 194.5 | 2.49 | 0.677 | 0.0614 |
| 4 | 199.9 | 2.51 | 0.550 | 0.0595 |
| 5 | 201.9 | 2.50 | 0.458 | 0.0521 |

TABLE 6
LPCVD Anti-Reflective Coating After Plasma Treatment

| | Anti-Reflective | | | |
|---|---|---|---|---|
| | Coating | Refractive | Extinction | |
| Wafer | Thickness (Å) | Index n | Coefficient k | Reflectance |
| 1 | 199.4 | 2.41 | 0.920 | 0.1067 |
| 2 | 197.8 | 2.48 | 0.776 | 0.0819 |
| 3 | 193.0 | 2.49 | 0.683 | 0.0603 |
| 4 | 198.1 | 2.51 | 0.562 | 0.0573 |
| 5 | 200.4 | 2.50 | 0.458 | 0.0488 |

Note the relatively low variability in extinction coefficient and reflectance for the PECVD samples, and conversely the relatively high variability in the those parameters for the LPCVD sample wafers. Interestingly, the LPCVD samples were selected from central positions within the furnace tube. Thus, those wafers at the ends of the furnace tube would likely have demonstrated even greater variability in optical properties.

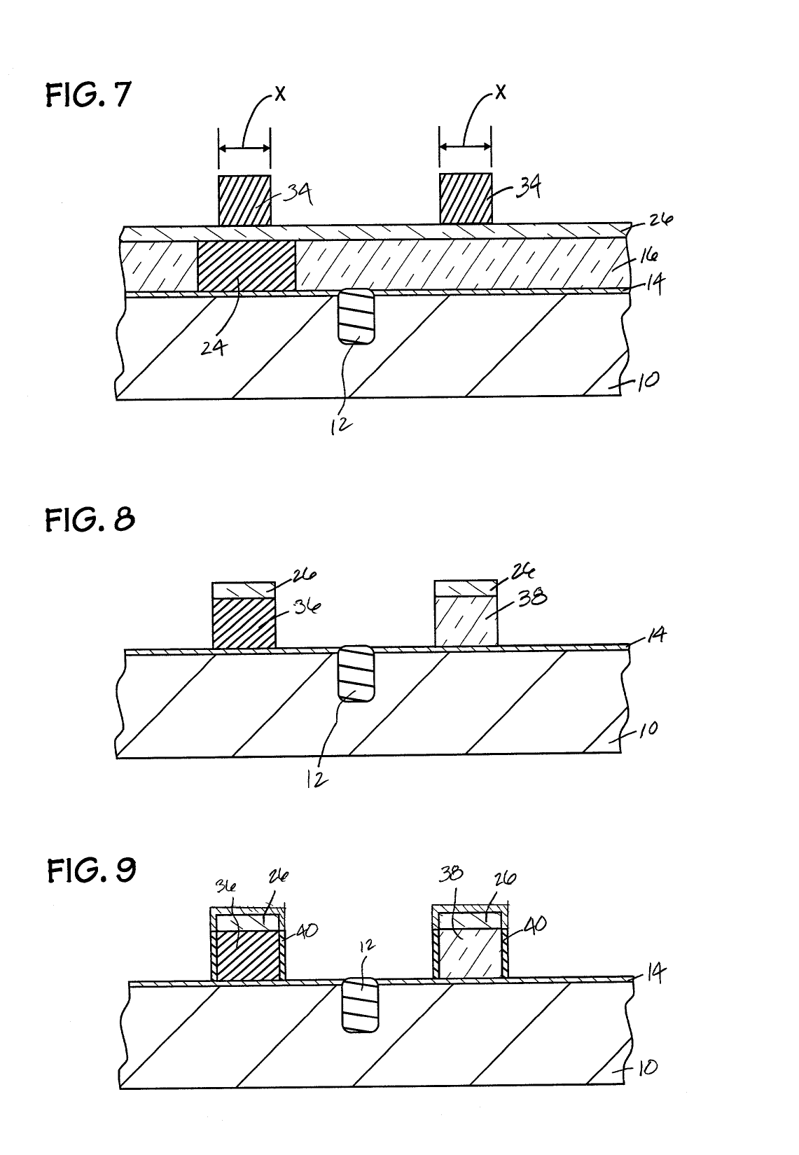

Following application of the anti-reflective coating 26, a suitable etch mask 34 is formed on the anti-reflective coating 26 with a pattern that corresponds to the desired floor plans or layouts of the conductor structures to be formed as shown in FIG. 7. The etch mask 34 may consist of well-known photoresist materials and may be patterned using well-known lithography techniques. The mask structures 34 may be formed with a lateral dimension X that may or may not correspond to the minimum feature size or critical dimension for the available lithographic patterning tools. The exposure of the photomask 34 is facilitated by the enhanced anti-reflective coating properties of not only the silicon-rich nitride layer 26 but also the overlying oxynitride interface 30. In this way, the propensity for resist footing due to standing wave effects is reduced.

Referring now to FIG. 8, the polysilicon layer 16 is anisotropically etched to the dielectric layer 14 to define circuit structures 36 and 38. The etch may be performed using well-known reactive ion etching, chemical plasma etching or other well-known anisotropic etching techniques and may use a variety of well-known chemistries suitable for etching silicon nitride and polysilicon. For example, a CF₄ and argon mixture may be used to break through the anti-reflective coating 26. Thereafter, the chemistry may be changed to a chemistry suitable for etching polysilicon, such as HBr, Cl₂ and CF₄. Near the polysilicon etch endpoint, the chemistry may be changed to HBr and argon to etch down to the dielectric film 14.

Following the etch definition of the circuit structures 36 and 38, the mask 34 may be stripped by well-known ashing, solvent stripping or combinations of the two techniques as shown in FIG. 8. A cleaning step, such as well-known RCA solvent techniques may follow resist strip.

Referring now to FIG. 9, a protective oxide film 40 is formed on the sidewalls of the circuit structures 36 and 38 and over the anti-reflecting coating 26. The film 40 is designed to protect the circuit structures during subsequent etch removal of the anti-reflective coating 26. In an exemplary embodiment, a furnace oxidation in an oxygen/argon atmosphere may be performed at about 850 ° C. for about six minutes to yield the oxide film with a thickness of about 20 to 40 Å. The thermal oxidation will produce some thickening of the oxide film 14 and reduce the thickness of the silicon rich nitride film 26 through densification.

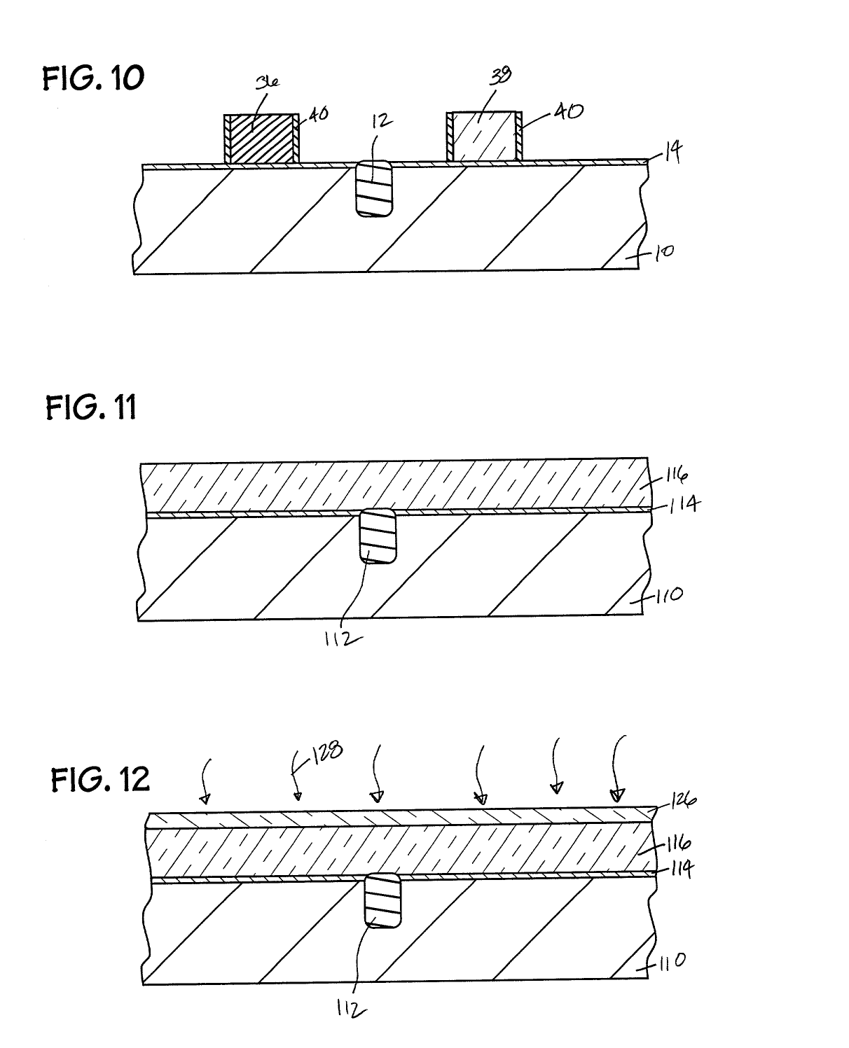

Referring now to FIG. 10, the silicon nitride film 26 shown in FIG. 9 may be stripped using, for example, a hot phosphoric acid dip or a plasma etch process as desired. The etch selectivity of the silicon rich nitride film 26 to the oxide film 40 provides for etch removal of the film 26 with preservation of much of the film 40. The final thickness of about 15 to 25 Å for the oxide film 40 serves as screen oxide for later-performed source/drain extension implants. The underlying oxide film 14 may be left in place at this point to maintain protection of the underlying substrate 10 as shown in FIG. 10 or may be optionally stripped away later using, for example, a HF dip or a plasma etch process as desired. In either event, the circuit structures 36 and 38 may now undergo further processing to establish circuit devices or other structures thereon depending upon the particular process flow desired.

An alternate exemplary process flow for processing a semiconductor substrate 110 may be understood by referring now to FIGS. 11-16. An isolation structure 112 may be formed in and a dielectric film 114 and a film 116 may be formed on the substrate 110 as generally described above in relation to the isolation structure 12 and films 14 and 16. However, in this embodiment, impurity introduction into the film 116 is delayed or eliminated from the process flow. This might be appropriate where, for example, the film 116 is composed of a metal or other conductor that does not require conductivity rendering impurities, or where adequate conductivity rendering doping may be supplied by later-performed implants. For the purposes of illustration, the film 116 is composed of undoped polysilicon.

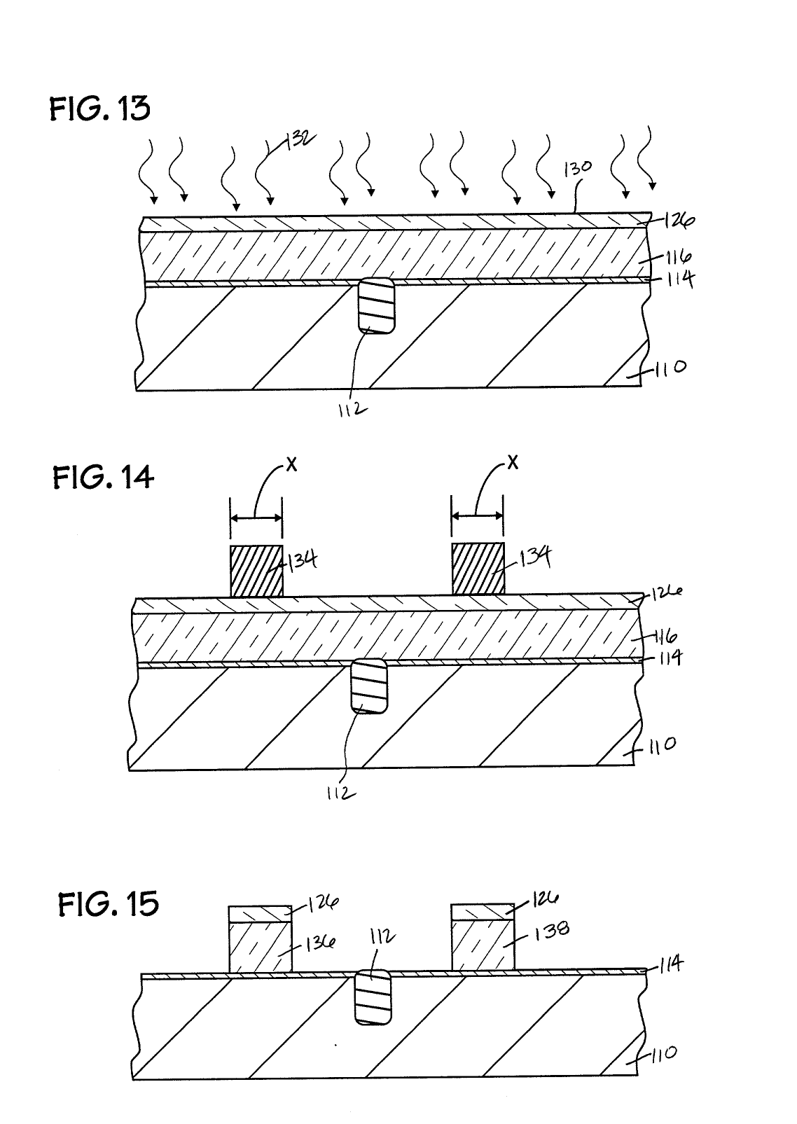

Referring now to FIGS. 12 and 13, an anti-reflective coating 126 may be applied in a plasma atmosphere 128. Thereafter, an oxynitride interface 130 may be established using an in-situ plasma atmosphere. The anti-reflective coating deposition and plasma treatment may be done using the parameters specified above for the anti-reflective coating 26 depicted in FIGS. 5 and 6.

Thereafter, an etch mask 134 shown in FIG. 14 may be applied as described above in conjunction with the mask 34. Again, the mask may be patterned with a lateral dimension X. Anisotropic etch definition of circuit structures 136 and 138 and mask stripping may follow masking as shown in FIG. 15. The etch and mask stripping processes may be as described above.

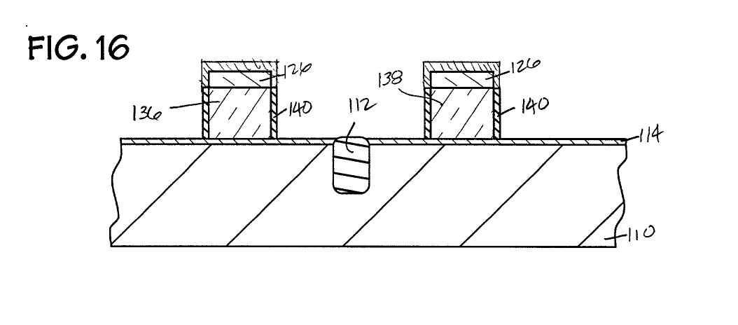

Referring now to FIG. 16, reoxidation to form protective oxide film 140 over the circuit structures 136 and 138 and the anti-reflective coating 126 may be performed using the techniques described above in conjunction with the oxide film 40 shown in FIG. 9. The anti-reflective coating 126 may then be stripped as described above.

While the invention may be susceptible to various modifications and alternative forms, specific embodiments have been shown by way of example in the drawings and have been described in detail herein. However, it should be understood that the invention is not intended to be limited to the particular forms disclosed. Rather, the invention is to cover all modifications, equivalents and alternatives falling within the spirit and scope of the invention as defined by the following appended claims.

What is claimed is:

1. A method of processing a substrate, comprising:
forming a film on the substrate; and
forming an anti-reflective coating on the film by first forming a silicon-rich nitride film on the film in a first plasma atmosphere and thereafter exposing the silicon-rich nitride film in-situ to a second plasma atmosphere containing oxygen to convert an upper portion of the silicon-rich nitride film to silicon oxynitride.

2. The method of claim 1, wherein the step of forming the film on the substrate comprises depositing polysilicon.

3. The method of claim 2, comprising introducing a conductivity rendering impurity into a portion of the polysilicon film.

4. The method of claim 3, wherein the conductivity rendering impurity is introduced by ion implantation.

5. The method of claim 4, wherein the ion implantation is performed through a mask that defines the layout of the portion of the polysilicon film.

6. The method of claim 1, comprising forming a photoresist mask on the silicon-rich nitride film and etching the silicon-rich nitride film to define a circuit structure.

7. The method of claim 6, wherein the etch to define the circuit structure exposes opposing sidewalls of the circuit structure.

8. The method of claim 7, comprising forming an oxide film on the exposed sidewalls.

9. The method of claim 8, comprising removing the anti-reflective coating after forming the oxide film on the sidewalls.

10. The method of claim 1, wherein the silicon-rich nitride film is formed by plasma enhanced chemical vapor deposition with an atmosphere containing silane and ammonia.

11. The method of claim 10, wherein the ratio of silane flow to ammonia flow is about 0.51 to 0.61.

12. The method of claim 1, wherein the plasma atmosphere containing oxygen further comprises a nitrogen bearing species.

13. The method of claim 12, wherein the nitrogen bearing species comprises N₂O, NO or NO₂.

14. A method of processing a substrate, comprising:
forming a polysilicon film on the substrate;
forming an anti-reflective coating on the polysilicon film by first forming a silicon-rich nitride film on the polysilicon film by plasma enhanced chemical vapor deposition and thereafter exposing the silicon-rich nitride film in-situ to a plasma atmosphere containing oxygen to convert an upper portion of the silicon-rich nitride film to silicon oxynitride;
forming a mask on the silicon-rich nitride film; and
etching unmasked portions of the silicon-rich nitride film to define a circuit structure from the polysilicon film.

15. The method of claim 14, comprising introducing a conductivity rendering impurity into a portion of the polysilicon film.

16. The method of claim 15, wherein the conductivity rendering impurity is introduced by ion implantation.

17. The method of claim 16, wherein the ion implantation is performed through a mask that defines the layout of the portion of the polysilicon film.

18. The method of claim 14, wherein the etch to define the circuit structure exposes opposing sidewalls of the circuit structure.

19. The method of claim 18, comprising forming an oxide film on the exposed sidewalls.

20. The method of claim 20, comprising removing the anti-reflective coating after forming the oxide film on the sidewalls.

21. The method of claim 14, wherein the silicon-rich nitride film is formed by plasma enhanced chemical vapor deposition with an atmosphere containing silane and ammonia.

22. The method of claim 21, wherein the ratio of silane flow to ammonia flow is about 0.51 to 0.61.

23. The method of claim 14, wherein the plasma atmosphere containing oxygen further comprises a nitrogen bearing species.

24. The method of claim 23, wherein the nitrogen bearing species comprises N₂O, NO or NO₂.

25. A circuit device comprising:
a semiconductor substrate;
a film positioned on the substrate; and
an anti-reflective coating positioned on the film, the anti-reflective having a silicon-rich nitride portion positioned on the film and an oxynitride interface positioned on the silicon-rich nitride portion.

26. The circuit device of claim 16, wherein the substrate comprises silicon.

27. The circuit device of claim 16, wherein the oxynitride film has an extinction coefficient of about 0.65 to 0.75.

28. The circuit device of claim 26, wherein the film comprises polysilicon.
